(19) United States
(12) Patent Application Publication
(10) Pub. No.: US 2012/0204388 A1
(43) Pub. Date: Aug. 16, 2012

(54) METHOD OF MANUFACTURING PIEZOELECTRIC VIBRATING REED, PIEZOELECTRIC VIBRATOR, OSCILLATOR, ELECTRONIC APPARATUS, AND RADIO TIMEPIECE

(76) Inventor: Daiki Irokawa, Chiba-shi (JP)

(21) Appl. No.: 13/369,599

(22) Filed: Feb. 9, 2012

(30) Foreign Application Priority Data
Feb. 14, 2011 (JP) 2011-029127

(51) Int. Cl. H01L 41/22

(52) U.S. Cl. 29/25.35

(57) ABSTRACT

A method of manufacturing a piezoelectric vibrating reed includes an electrode mark group detecting process of detecting a wafer side mark group and an electrode mask side mark group, and an electrode mask placing process of placing the electrode film mask on the wafer while aligning the wafer side mark group and the electrode mask side mark group, wherein the wafer side mark group and the electrode mask side mark group are constituted by marks having sizes different from each other, the smallest wafer side mark and the electrode mask side mark are used for the alignment of the mutual marks, respectively, and the wafer side mark and the electrode mask side mark except for the smallest wafer side mark and the electrode mask side mark are used in the electrode mark group detecting process.

### RELATED APPLICATIONS

This application claims priority under 35 U.S.C. §119 to Japanese Patent Application No. 2011-029127 filed on Feb. 14, 2011, the entire content of which is hereby incorporated by reference.

### BACKGROUND OF THE INVENTION

1. Field of the Invention

The present invention relates to a method of manufacturing a piezoelectric vibrating reed, a piezoelectric vibrator, an oscillator, an electronic apparatus, and a radio timepiece.

2. Description of the Related Art

In recent years, in mobile phones or portable information terminals, a piezoelectric vibrator which has a piezoelectric vibrating piece using a crystal or the like is used as a time source, a control signal timing source, a reference signal source or the like. This kind of piezoelectric vibrating reed includes a piezoelectric plate that is formed of a piezoelectric material, and an electrode portion that vibrates the piezoelectric plate when the voltage is applied. Herein, a plurality of piezoelectric vibrating reeds is manufactured at one time by the use of a wafer formed of crystal of a piezoelectric material.

More specifically, a resist film is first applied from a top of a protective film to a front surface and a back surface of a wafer, and a mask for forming the external form of the piezoelectric plate is placed on the resist film. Next, the resist film is irradiated with ultraviolet ray via the mask, and an etching pattern (a resist pattern) is exposed onto the resist film. After the mask is detached, the resist film is developed to remove the exposure portion, and then metal etching is performed to remove the exposed protective film from the exposure portion. In addition, the resist film is removed, the crystal etching is performed to etch the exposed wafer from the removed portion of the protective film, and then the protective film is removed, whereby the external form of the piezoelectric plate is formed.

Next, the electrode film is formed by vapor-depositing and sputtering an electrode material on the wafer formed with the external form of the piezoelectric plate, and the resist film is formed thereon. Moreover, a mask formed with a desired electrode and wiring pattern is placed on the resist film and is irradiated with ultraviolet ray to expose an etching pattern (a resist pattern) to the resist film. After that, the resist film is developed to remove the exposure portion, the surface of the electrode film is exposed, and the exposed surface is etched to expose the surface of the wafer, thereby polarizing the electrode film, whereby a desired electrode and wiring are obtained.

Herein, the masks placed on the front surface of the wafer and the back surface of the wafer are aligned while being visually checked so that the respective formed etching patterns completely overlap each other. At this time, since the etching patterns of each mask are completely identical to each other, a position deviation is easily generated in both of the masks. For this reason, a technique is disclosed which attempts to prevent the position deviation between the respective masks by forming a plurality of alignment marks of the same shape in each mask and aligning the mutual alignment marks (see JP-A-2003-186210).

However, when attempting to prevent the position deviation of the masks using the plurality of alignment marks, the sizes of the plurality of alignment marks affect the workability of the aligning or the accuracy of the aligning.

That is, when the alignment mark is large, a worker easily specifies the alignment mark and the workability of the aligning is improved, but the accuracy of the aligning drops. Meanwhile, when the alignment mark is small, the accuracy of the aligning can be increased, but a worker will find it hard to specify the alignment mark, and the workability of the aligning drops.

Furthermore, the same is also true for the aligning of the mask that is used when forming the electrode on the piezoelectric plate. That is, even when forming the alignment marks in the mask for forming the electrode and the wafer, respectively, the workability of the aligning drops or the accuracy of the aligning is degraded, due to the size of the alignment mark.

Thus, the present invention was made in view of the above circumstances, and an object thereof is to provide a method of manufacturing a piezoelectric vibrating reed that is able to increase the accuracy of the aligning and easily and accurately form a piezoelectric plate or an electrode while improving the workability of the aligning of the mask, a piezoelectric vibrator, an oscillator, an electronic apparatus, and a radio timepiece.

### SUMMARY OF THE INVENTION

In order to solve the problem, according to a first aspect of the present invention, there is provided a method of manufacturing a piezoelectric vibrating reed that includes a piezoelectric plate, and an electrode portion which vibrates the piezoelectric plate when voltage is applied, the method includes an external form forming process of applying a piezoelectric plate forming mask material onto both surfaces of a wafer formed of a piezoelectric material, then, placing a pair of external form masks prepared for the forming of piezoelectric plate, and then irradiating light via the external form masks to form the external form of the piezoelectric plate; and a resist pattern forming process of applying an electrode film mask material to the wafer formed with the external form of the piezoelectric plate, then placing an electrode film mask prepared for an electrode film, and then irradiating light via the electrode film mask to form a resist pattern, wherein the resist pattern forming process has an electrode mark group detecting process of detecting a wafer side mark group formed in the wafer, an electrode mask side mark group formed in the electrode film mask, and an electrode mask placing process of placing the electrode film mask on the wafer while aligning the wafer side mark group and the electrode mask side mark group, the wafer side mark group is constituted by at least two wafer side marks having sizes different from each other, the electrode mask side mark group is constituted by at least two electrode mask side marks having sizes different from each other, the smallest wafer side mark and electrode mask side mark are used for the alignment of the mutual marks, respectively, and all of the wafer side marks and the electrode mask side mark except for the smallest wafer side mark and electrode mask side mark are used in the electrode mark group detecting process.

By such a method, by sequentially specifying from the largest wafer side mark and the largest electrode mask side mark, it is possible to rapidly specify the smallest wafer side mark and the smallest electrode mask side mark. Furthermore, by aligning the respective masks using the smallest wafer side mark and the smallest electrode mask side mark, the aligning can accurately be performed. For this reason, the resist pattern forming process can easily and accurately be performed.

In the method of manufacturing the piezoelectric vibrating reed according to a second aspect of the present invention, each wafer side mark and each electrode mask side mark may be placed in a predetermined arrangement pattern.

By such a method, since it is possible to easily predict the positions of the smallest wafer side mark and the smallest electrode mask side mark at the point in time when specifying the largest wafer side mark and the largest electrode mask side mark, it is possible to improve an operation efficiency after specifying the largest wafer side mark and the largest electrode mask side mark until specifying the smallest wafer side mark and the smallest electrode mask side mark.

In the method of manufacturing the piezoelectric vibrating reed according to a third aspect of the present invention, the respective wafer side marks may be configured so that another wafer side mark is placed in a forming range of the largest wafer side mark, and the respective electrode mask side marks may be configured so that another electrode mask side mark is placed in a forming range of the largest electrode mask side mark.

By such a method, it is possible to easily specify the smallest wafer side mark, and the smallest electrode mask side mark. For this reason, the workability of the aligning of each mask can be improved.

According to a fourth aspect of the present invention, there is provided a method of manufacturing a piezoelectric vibrating reed that includes a piezoelectric plate, and an electrode portion which vibrates the piezoelectric plate when voltage is applied, the method includes an external form forming process of applying a piezoelectric plate forming mask material onto both surfaces of a wafer formed of a piezoelectric material, then, placing a pair of external form masks prepared for the forming of piezoelectric plate, and then irradiating light via the external form masks to form an external form of the piezoelectric plate; and a resist pattern forming process of applying an electrode film mask material to the wafer formed with the external form of the piezoelectric plate, then placing an electrode film mask prepared for an electrode film, and then irradiating light via the electrode film mask to form a resist pattern, wherein the external form forming process has an external form mark group detecting process of detecting an external form mask side mark group formed in each external form mask, and an external form mask placing process of placing each external form mask on the wafer while aligning the positions of the external form mask side mark group of each external form mask, the external form mask side mark group is constituted by at least two external form mask side marks having sizes different from each other, the smallest external form mask side mark formed in each external form mask is used for the alignment of the mutual marks, and all of the external form mask side marks except for the smallest external form mask side mark are used in the external form mark group detecting process.

By such a method, by sequentially specifying from the largest external form mask side mark, it is possible to rapidly specify the smallest external form mask side mark. Furthermore, by aligning the respective masks using the smallest external form mask side mark, the aligning can accurately be performed. For this reason, the external form forming process can easily and accurately be performed.

In the method of manufacturing the piezoelectric vibrating reed according to a fifth aspect of the present invention, each external form mask side mark is placed in a predetermined arrangement pattern.

By such a method, since it is possible to easily predict the position of the smallest external form mask side mark at the point in time when specifying the largest external form mask side mark, it is possible to improve an operation efficiency after specifying the largest external form mask side mark until specifying the smallest external form mask side mark.

In the method of manufacturing the piezoelectric vibrating reed according to a sixth aspect of the present invention, the respective external form mask side marks are configured so that another external form mask side mark is placed in a forming range of the largest external form mask side mark.

By such a method, it is possible to easily specify the smallest external form mask side mark. For this reason, the workability of the aligning of each mask can be improved.

According to a seventh aspect of the present invention, a piezoelectric vibrator is provided which is manufactured by the use of the method of manufacturing the piezoelectric vibrating reed according to any one of first to sixth aspects.

By such a configuration, it is possible to provide the piezoelectric vibrator that is able to easily and accurately form the piezoelectric plate or the electrode by increasing the accuracy of the aligning while improving workability of the aligning of each mask.

According to an eighth aspect of the present invention, an oscillator is provided which is configured so that the piezoelectric vibrator according to a seventh aspect is electrically connected to an integrated circuit as an oscillating element.

By such a configuration, the oscillator of high quality can effectively be manufactured, whereby a reduction in the cost of the oscillator can be promoted.

According to a fifth aspect of the present invention, an electronic apparatus is provided which is configured so that the piezoelectric vibrator according to the seventh aspect is electrically connected to a count portion.

By such a configuration, the electronic apparatus of high quality can effectively be manufactured, whereby a reduction in the cost of the electronic apparatus can be promoted.

According to a sixth aspect of the present invention, a radio timepiece is provided which is configured so that the piezoelectric vibrator according to the seventh aspect is electrically connected to a filter portion.

By such a configuration, the radio timepiece of high quality can effectively be manufactured, whereby a reduction in the cost of the radio timepiece can be promoted.

According to the present invention, by sequentially specifying from the largest wafer side mark and the largest electrode mask side mark, it is possible to rapidly specify the smallest wafer side mark and the smallest electrode mask side mark. Furthermore, by aligning the respective masks using the smallest wafer side mark and the smallest electrode mask side mark, the aligning can accurately be performed. For this reason, the resist pattern forming process can easily and accurately be performed.

Furthermore, by sequentially specifying from the largest external form mask side mark, it is possible to rapidly specify the smallest external form mask side mark. Furthermore, by aligning the respective masks using the smallest external form mask side mark, the aligning can accurately be performed. For this reason, the external form forming process can easily and accurately be performed.

### BRIEF DESCRIPTION OF THE DRAWINGS

FIG. 1 is an external perspective view in which a piezoelectric vibrator in an embodiment of the present invention is viewed from a lead substrate side.

FIG. 2 is a diagram in which a piezoelectric vibrating reed is viewed from above with the lead substrate in the embodiment of the present invention detached therefrom.

FIG. 3 is a cross-sectional view of the piezoelectric vibrator taken along line A-A of FIG. 2.

FIG. 4 is an exploded perspective view of the piezoelectric vibrator in the embodiment of the present invention.

FIG. 5 is a top view of the piezoelectric vibrating reed in the embodiment of the present invention.

FIG. 6 is a bottom view of the piezoelectric vibrating reed in the embodiment of the present invention.

FIG. 7 is a cross-sectional view taken along line B-B of FIG. 5.

FIG. 8 is a schematic plan view of an external form mask in the embodiment of the present invention.

FIG. 9 is a schematic plan view of an electronic film mask in the embodiment of the present invention.

FIG. 10 is a schematic plan view of a work stage in the embodiment of the present invention.

FIG. 11 is a detail view of each mark group in the embodiment of the present invention.

FIG. 12 is a flow chart of a method of manufacturing the piezoelectric vibrating reed in the embodiment of the present invention.

FIG. 13 is a process diagram of a resist pattern forming process in an external form forming process in the embodiment of the present invention.

FIGS. 14A to 14D are operation process diagrams of an external form mask side mark group in the embodiment of the present invention that show behaviors of each process.

FIG. 15 is a plan view of a wafer in which the external form forming process is finished in the embodiment of the present invention.

FIGS. 16A to 16C are process diagrams of resist pattern forming process in the embodiment of the present invention that show behaviors of each process.

FIGS. 17A to 17D are operation process diagrams for aligning an electrode mask side mark group to a wafer side mark group in the embodiment of the present invention.

FIG. 18 is a configuration diagram of an oscillator in the embodiment of the present invention.

FIG. 19 is a configuration diagram of a portable information apparatus in the embodiment of the present invention.

FIG. 20 is a configuration diagram that shows an embodiment of a radio timepiece in the embodiment of the present invention.

FIG. 21 is a detail view of another embodiment of each mark group in the embodiment of the present invention.

### DETAILED DESCRIPTION OF THE PREFERRED EMBODIMENTS

### (Piezoelectric Vibrator)

Next, an embodiment of the present invention will be described based on the drawings.

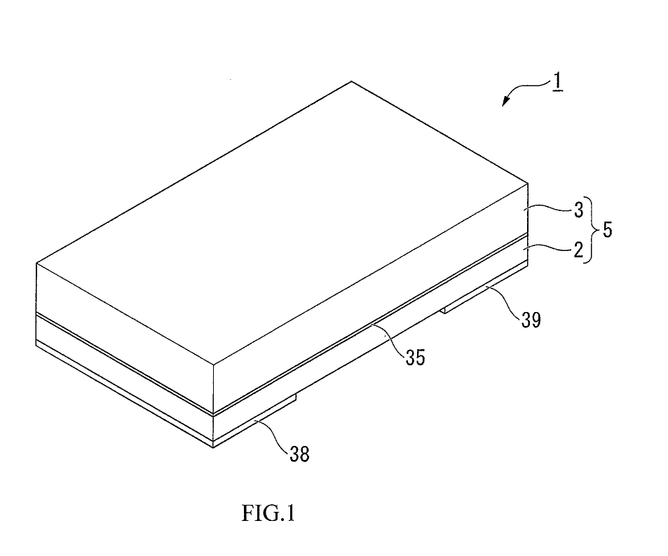

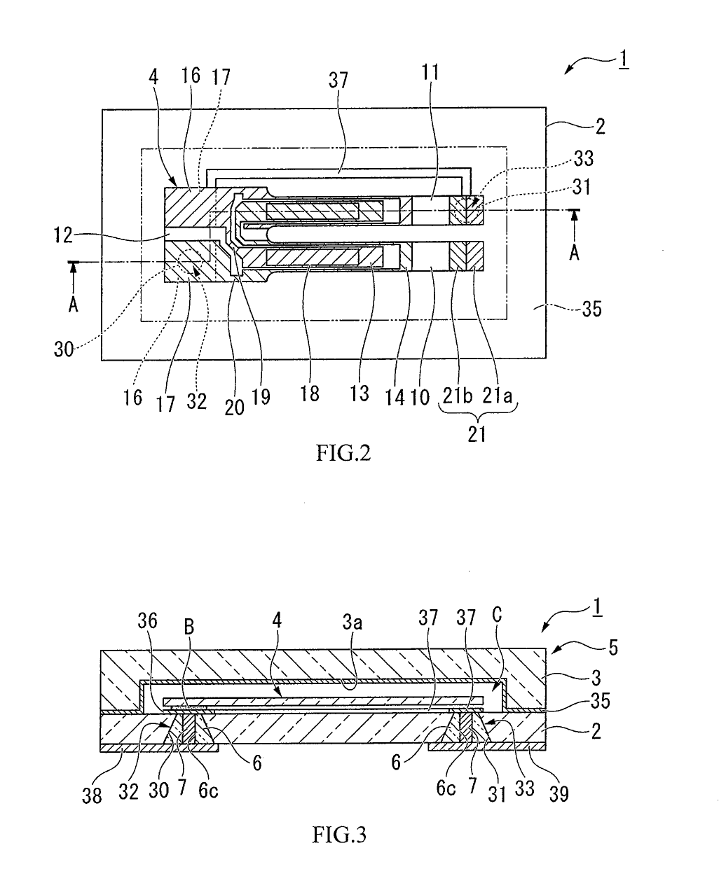

FIG. 1 is an external perspective view in which a piezoelectric vibrator is viewed from a lead substrate side. FIG. 2 is an internal configuration diagram of the piezoelectric vibrator in which a piezoelectric vibrating reed is viewed from above with the lead substrate detached therefrom.

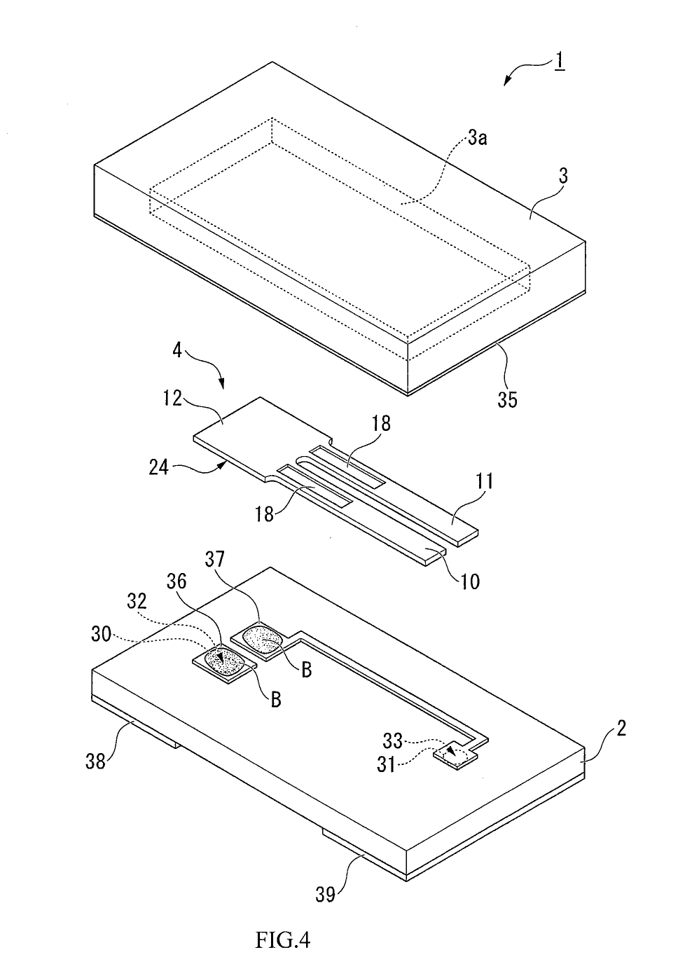

FIG. 3 is a cross-sectional view of the piezoelectric vibrator taken along line A-A of FIG. 2. FIG. 4 is an exploded perspective view of the piezoelectric vibrator.

As shown in FIGS. 1 to 4, a piezoelectric vibrator 1 is a surface mount type piezoelectric vibrator which has a box-shaped package 5 in which a base substrate 2 and a lead substrate 3 are anodically bonded to each other via a bonding material 35, and has a piezoelectric vibrating reed 4 that is sealed in a cavity C in an inner portion of the package 5. In addition, in FIG. 4, in order to clarify the drawings, an excitation electrode 15, drawing electrodes 19, 20, mount electrodes 16 and 17, and a weight metal film 21 are not shown.

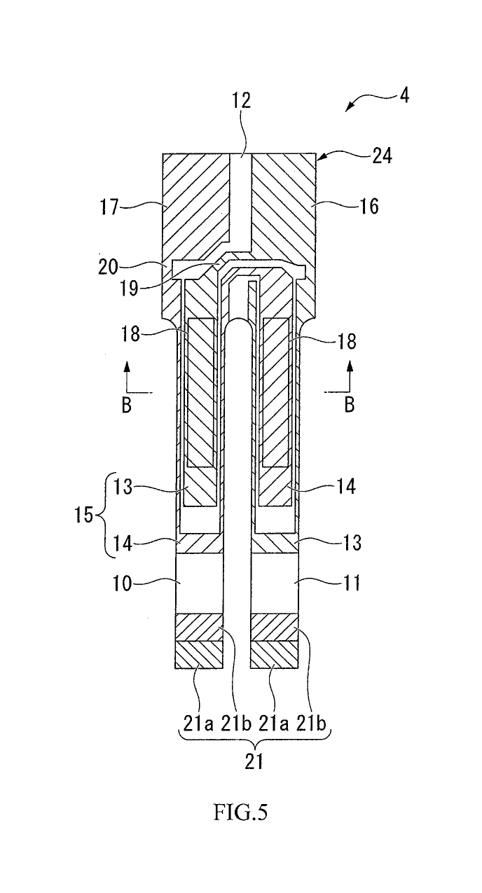

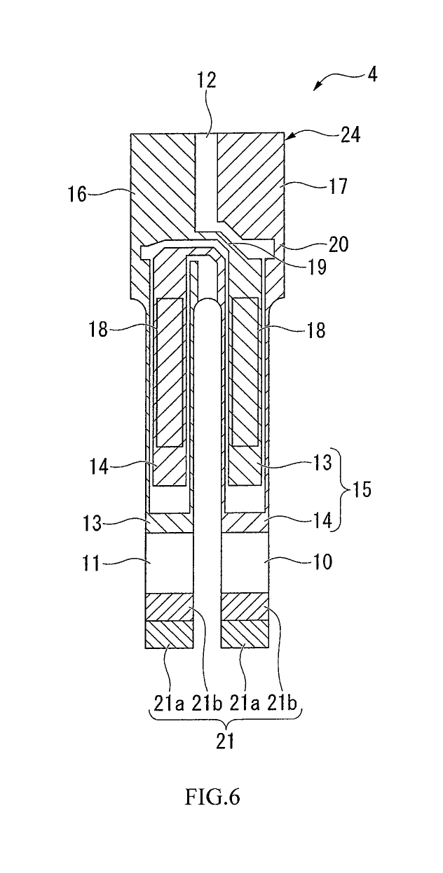

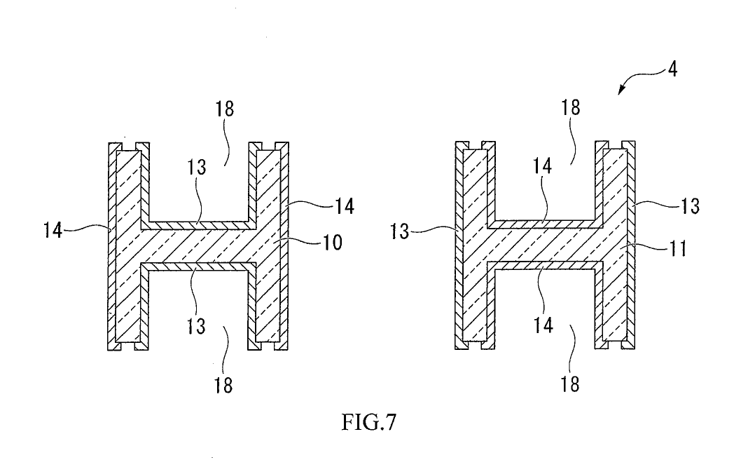

FIG. 5 is a top view of the piezoelectric vibrating reed that constitutes the piezoelectric vibrator, FIG. 6 is a bottom view of the piezoelectric vibrating reed, and FIG. 7 is a cross-sectional view taken along line B-B of FIG. 5.

As shown in FIGS. 5 to 7, the piezoelectric vibrating reed 4 is vibrated when a predetermined voltage is applied, and includes a tuning fork-shaped piezoelectric plate 24 that is formed of a piezoelectric material such as crystal, lithium tantalite, and lithium niobate.

The piezoelectric plate 24 has a pair of vibration arm portions 10 and 11 disposed in parallel, and a base portion 12 that integrally fixes a proximal end side of the pair of vibration arm portions 10 and 11. Furthermore, on the outer surface of the piezoelectric plate 24, there are provided an excitation electrode 15 that is constituted by a first excitation electrode 13, which vibrates the pair of vibration arm portions 10 and 11, and a second excitation electrode 14, and mount electrodes 16 and 17, which are electrically connected to the first excitation electrode 13 and the second excitation electrode 14.

Furthermore, in the piezoelectric plate 24, on both main surfaces of the pair of vibration arm portions 10 and 11, groove portions 18, which are formed along the longitudinal direction of the vibration arm portions 10 and 11, respectively, are formed. The groove portions 18 are formed so as to reach a portion near approximately the middle from the proximal end sides of the vibration arm portions 10 and 11.

The excitation electrode 15 including the first excitation electrode 13 and the second excitation electrode 14 is an electrode that vibrates the pair of vibration arm portions 10 and 11 in a direction approaching or separated from each other at a predetermined frequency, and is patterned and formed on the outer surfaces of the pair of vibration arm portions 10 and 11 in the state of being electrically separated, respectively.

Specifically, the first excitation electrode 13 is mainly formed on the groove portions 18 of one vibration arm portions 10 and on both surfaces of the other vibration arm portions 11. Furthermore, the second excitation electrode 14 is mainly formed on both surfaces of one vibration arm portion 10 and the groove portion 18 of the other vibration arm portion 11.

In addition, the first excitation electrode 13 and the second excitation electrode 14 are electrically connected to the mount electrodes 16 and 17 via the drawing electrodes 19 and 20 on both main surfaces of the base portion 12, respectively. The piezoelectric vibrating reed 4 is applied with the voltage via the mount electrodes 16 and 17.

Furthermore, the outer surfaces of the pair of vibration arm portions 10 and 11 are coated with a frequency adjusting weight metal film 21 so that the vibration state thereof is vibrated in a predetermined frequency range. The weight metal film 21 is formed of, for example, silver (Ag) or gold (Au), and is divided into a rough adjustment film 21a that is used when roughly adjusting the frequency, and a minute adjustment film 21b used when minutely adjusting the frequency. By performing the frequency adjustment by the use of the weights of the rough adjustment film 21a and the minute adjustment film 21b, it is possible to put the frequencies of the pair of vibration arm portions 10 and 11 within an objective frequency of the apparatus.

As shown in FIGS. 3 and 4, the piezoelectric vibrating reed 4 configured in this manner is bump-bonded to an upper surface of the base substrate 2 by the use of a bump B such as gold. More specifically, on two bumps B formed on leading electrodes 36 and 37 described below patterned on the upper surface of the base substrate 2, the pair of mount electrodes 16 and 17 is bump-bonded in the state of contact state, respectively.

As a result, the piezoelectric vibrating reed 4 is supported in the state of floating from the upper surface of the base substrate 2, and the mount electrodes 16 and 17 and the leading electrodes 36 and 37 are electrically connected to each other, respectively.

As shown in FIGS. 1, 3, and 4, the lead substrate 3 is a transparent insulation substrate formed of a glass material, for example, a soda-lime glass, and is formed in a plate shape. At the bonding surface side bonded with the base substrate 2, a rectangular concave portion 3a is formed into which the piezoelectric vibrating reed 4 enters. The concave portion 3a is a concave portion for the cavity becoming the cavity C that accommodates the piezoelectric vibrating reed 4 when both of the substrates 2 and 3 overlap with each other.

On the whole lower surface of the lead substrate 3, a bonding material 35 for the anodic bonding is formed. Specifically, the bonding material 35 is formed all over the bonding surface with the base substrate 2 and all over the inner surface of the concave portion 3a. The bonding material 35 of the present invention is formed by Si film, but the bonding material 35 is also able to be formed of Al. Furthermore, it is also possible to adopt a Si bulk material having low resistance due to doping or the like, as the bonding material. Furthermore, the bonding material 35 and the base substrate 2 are anodically bonded to each other in the state of causing the concave portion 3a to face the base substrate 2 side, whereby the cavity C is hermetically sealed.

As shown in FIGS. 1 to 4, the base substrate 2 is a transparent insulation substrate formed of a glass material like the lead substrate 3, for example, a soda-lime glass, and is formed in a plate shape having a size that can overlap the lead substrate 3. The base substrate 2 is formed with a pair of through holes 30 and 31 that penetrates the base substrate 2. At this time, the pair of through holes 30 and 31 is formed so as to enter the cavity C.

More specifically, among the through holes 30 and 31, one through hole 30 is formed at a position corresponding to the base portion 12 side of the mounted piezoelectric vibrating reed 4. Furthermore, the other through hole 31 is formed at a position corresponding to the tip ends of the vibration arm portions 10 and 11. Furthermore, the through holes 30 and 31 are formed in a taper-shaped cross section in which the diameters thereof are gradually reduced from the lower surface of the base substrate 2 toward the upper surface.

In addition, in the present embodiment, a case was described where the respective through holes 30 and 31 are formed in the taper-shaped cross section, but a through hole may be adopted which directly penetrates the base substrate 2, without being limited thereto. In any case, the through hole may penetrate the base substrate 2.

Moreover, the pair of through holes 30 and 31 is formed with a pair of penetration electrodes 32 and 33 that is formed so as to bury the respective through holes 30 and 31.

As shown in FIG. 3, the penetration electrodes 32 and 33 are formed by a barrel 6 integrally fixed to the through holes 30 and 31 by burning, and a core portion 7. The respective penetration electrodes 32 and 33 play a role in completely blocking the through holes 30 and 31 to maintain the air-tightness in the cavity C and conducting external electrodes 38 and 39 described later and the leading electrodes 36 and 37.

The barrel 6 is burned by a paste-like glass flit. The barrel 6 has flat both ends and is formed in a cylindrical shape having approximately the same thickness as the base substrate 2. Moreover, in the center of the barrel 6, the core portion 7 is disposed so as to penetrate the barrel 6. Additionally, in the present embodiment, according to the shapes of the through holes 30 and 31, the external form of the barrel 6 is formed in a conical shape (a taper-shaped cross section). Moreover, the barrel 6 is burned in the state of being buried in the through holes 30 and 31, whereby the barrel 6 is firmly fixed to the through holes 30 and 31.

The core portion 7 is a conductive core formed in a columnar shape by a metallic material, has both ends flat like the barrel 6, and is formed so as to have approximately the same thickness as that of the base substrate 2. The core portion 7 is situated in the center hole 6c of the barrel 6, and is firmly fixed to the barrel 6 by the burning of the barrel 6. Furthermore, in the penetration electrodes 32 and 33, the electrical conductivity is ensured through the conductive core portion 7.

As shown in FIGS. 1 to 4, at the upper surface side (the bonding surface side with the lead substrate 3 bonded thereto) of the base substrate 2, the pair of leading electrodes 36 and 37 is patterned by a conductive material (for example, aluminum). The pair of leading electrodes 36 and 37 is patterned so as to electrically connect one penetration electrode 32 with one mount electrode 16 of the piezoelectric vibrating reed 4 and electrically connect the other penetration electrode 33 and the other mount electrode 17 of the piezoelectric vibrating reed 4, among the pair of penetration electrodes 32 and 33.

More specifically, one leading electrode 36 is formed immediately over the penetration electrode 32 so as to be situated immediately under the base portion 12 of the piezoelectric vibrating reed 4. Furthermore, the other leading electrode 37 is formed so as to be situated immediately over the other penetration electrode 33 after being drawn from a position adjacent to one leading electrode 36 to the tip sides of the vibration arm portions 10 and 11 along with the vibration arm portions 10 and 11.

Moreover, the bumps B are formed on the pair of leading electrodes 36 and 37, respectively, and the piezoelectric vibrating reed 4 is mounted by the use of the bumps B. As a result, one mount electrode 16 of the piezoelectric vibrating reed 4 is conducted to one penetration electrode 32 via one leading electrode 36. Additionally, the other mount electrode 17 is conducted to the other leading electrode 33 via the other leading electrode 37.

As shown in FIGS. 1, 3, and 4, on the lower surface of the base substrate 2, external electrodes 38 and 39 electrically connected to the pair of penetration electrodes 32 and 33 are formed. That is, one external electrode 38 is electrically connected to the first excitation electrode 13 of the piezoelectric vibrating reed 4 via one penetration electrode 32 and one leading electrode 36.

Furthermore, the other external electrode 39 is electrically connected to the second excitation electrode 14 of the piezoelectric vibrating reed 4 via the other penetration electrode 33 and the other leading electrode 37.

In the case of operating the piezoelectric vibrator 1 configured in this manner, a predetermined driving voltage is applied to the external electrodes 38 and 39 formed in the base substrate 2. As a result, it is possible to cause the electric current to flow in the excitation electrode 15 including the first excitation electrode 13 and the second excitation electrode 14 of the piezoelectric vibrating reed 4, whereby the pair of vibration arm portions 10 and 11 can be vibrated in a direction approaching and separated from each other at a predetermined frequency. Moreover, the vibration of the pair of vibration arm portions 10 and 11 can be used as a time source, a timing source of the control signal, a reference signal source or the like.

### (Method of Manufacturing Piezoelectric Vibrator)

Next, a method of forming the piezoelectric vibrating reed 4 by the use of the wafer S (see FIG. 11) formed of a piezoelectric material will be described.

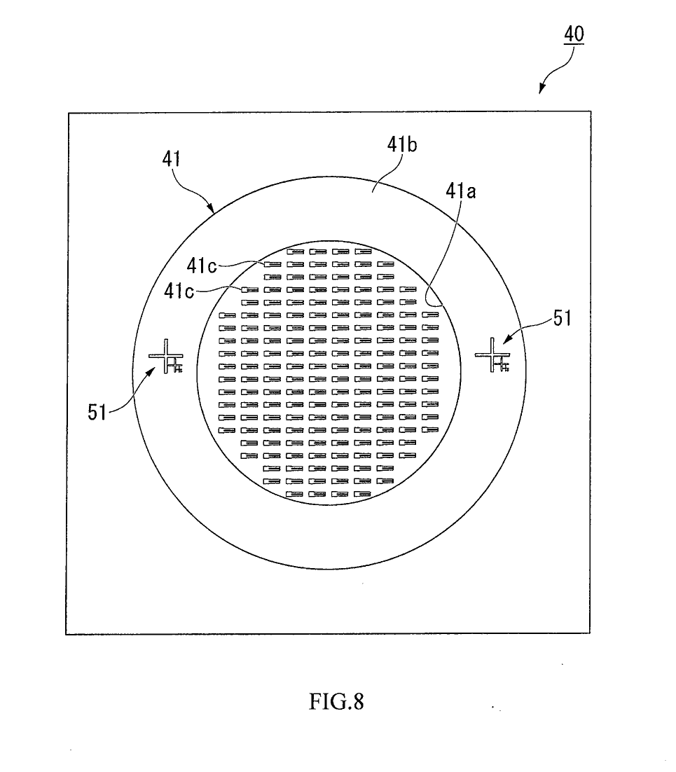

Firstly, a manufacturing apparatus 40 of the piezoelectric vibrating reed used in the manufacturing method will be described based on FIGS. 8 to 11.

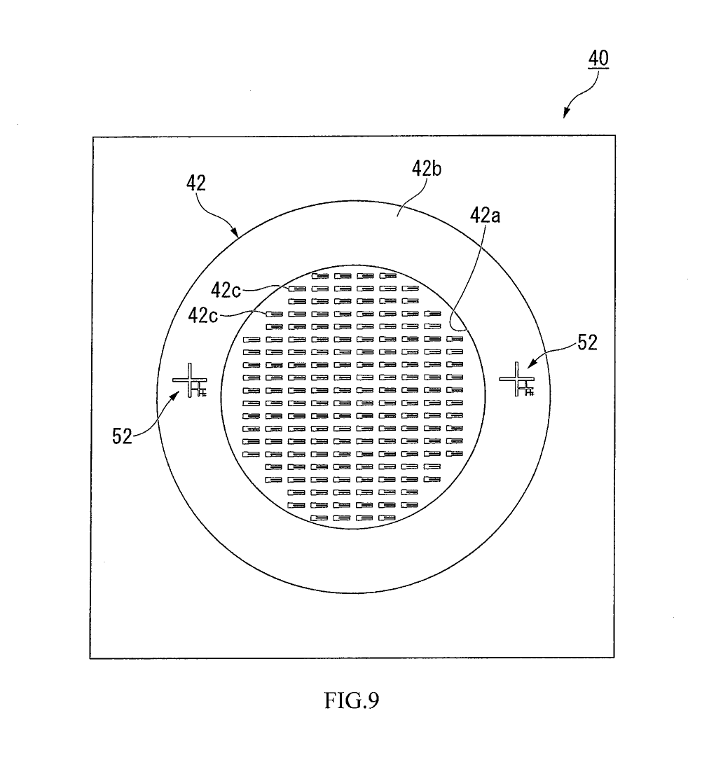

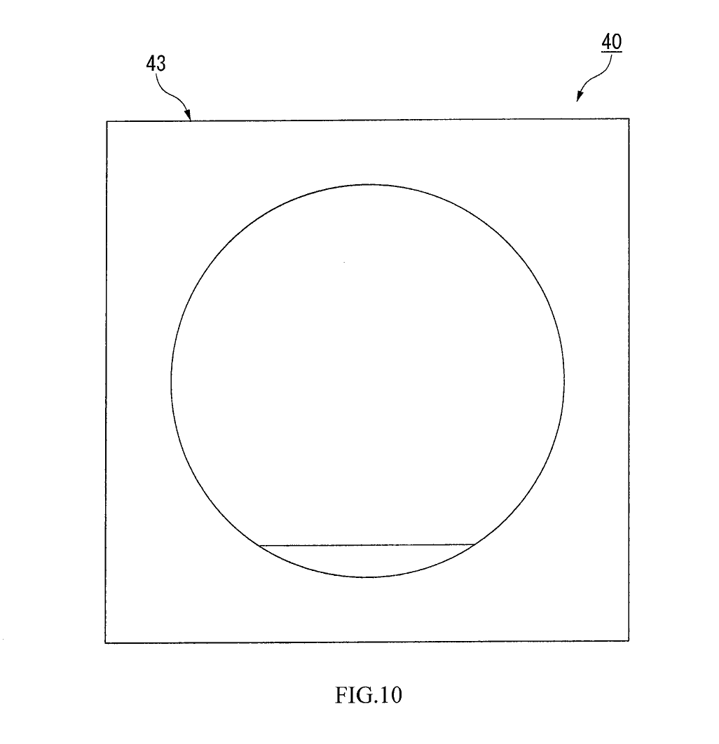

FIG. 8 is a schematic plan view of an external form mask, FIG. 9 is a schematic plane view of an electrode film mask, and FIG. 10 is a schematic plan view of a work stage.

As shown in FIGS. 8 to 10, the manufacturing apparatus 40 includes an external form mask 41 for forming an external form of the piezoelectric plate 24 (see FIGS. 5 and 6) in the wafer S, and a work stage 43 that mounts an electrode film mask 42 for forming the excitation electrode 15 (see FIGS. 5 and 6) and the wafer S on the piezoelectric plate 24.

The masks 41 and 42 include frame-shaped portions 41b and 42b having inner portions that are exposure regions 41a and 42a, respectively, and a plurality of coating portions 41c and 42c that is placed in the exposure regions 41a and 42a and is connected to the frame-shaped portions 41b and 42b via a connection portion (not shown). In addition, the respective coating portions 41c and 42c shown after FIG. 8 are configured so that the shape or the number thereof is simplified so as to clarify the drawings.

Herein, in the frame-shaped portion 41b of the external form mask 41, two external form mask side mark groups 51 are formed so as to be situated at both sides with a central portion of the external form mask 41 interposed therebetween. Meanwhile, in the frame-shaped portion 42b of the electrode film mask 42, tow electrode mask side mark group 52 are formed so as to be situated at both sides with the central portion of the electrode film mask 42 interposed therebetween. That is, the respective mark groups 51 and 52 are formed in the position corresponding to each other. The mark groups 51 and 52 are alignment marks that are used in the aligning of the corresponding masks 41 and 42 (details thereof will be described below).

FIG. 11 is a detail view of each mark group. In addition, since both of the respective mark groups 51 and 52 have the same shape, the respective mark groups 51 and 52 will be described by the use of the same drawing (FIG. 11).

As shown in FIG. 11, the external form mask side mark group 51 is constituted by a plurality (four in the present embodiment) of external mask side marks 51a to 51d. The respective marks 51a to 51d are formed in a cross shape and have the sizes different from each other. That is, from the largest external form mask side mark 51a to the smallest external form mask side mark 51d, the external form mask side marks 51b and 51c existing therebetween are sequentially formed smaller.

Furthermore, three external form mask side marks 51b, 51c, and 51d except for the largest external form mask side mark 51a are placed in a forming range W1 of the largest external form mask side mark 51a. Moreover, the respective marks 51a to 51d are placed in a predetermined arrangement pattern. The predetermined arrangement pattern may be arranged by a predetermined rule, and for example, in FIG. 11, the arrangement pattern is placed so as to gradually deviate from the largest external form mask side mark 51a to a right lower side of FIG. 11 in the sequence of the large mark.

Meanwhile, the electrode mask side mark group 52 is also configured in the same manner as the external form mask side mark group 51. That is, the electrode mask side mark group 52 is constituted by a plurality (four in the present embodiment) of electrode mask side marks 52a to 52d, and the sizes of the electrode mask side marks 52a to 52d are different from each other. Moreover, three electrode mask side marks 52b, 52c, and 52d except for the largest mask side mark 52a are placed in the forming range W1 of the largest external form mask side mark 52a in a predetermined arrangement pattern.

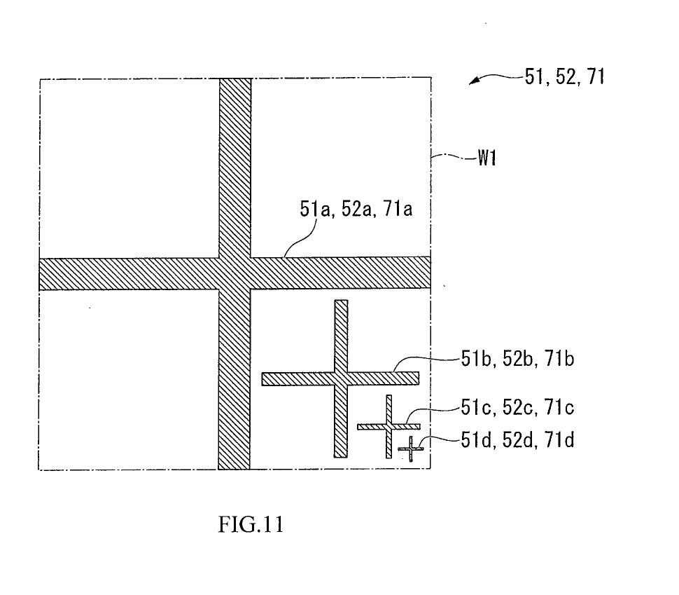

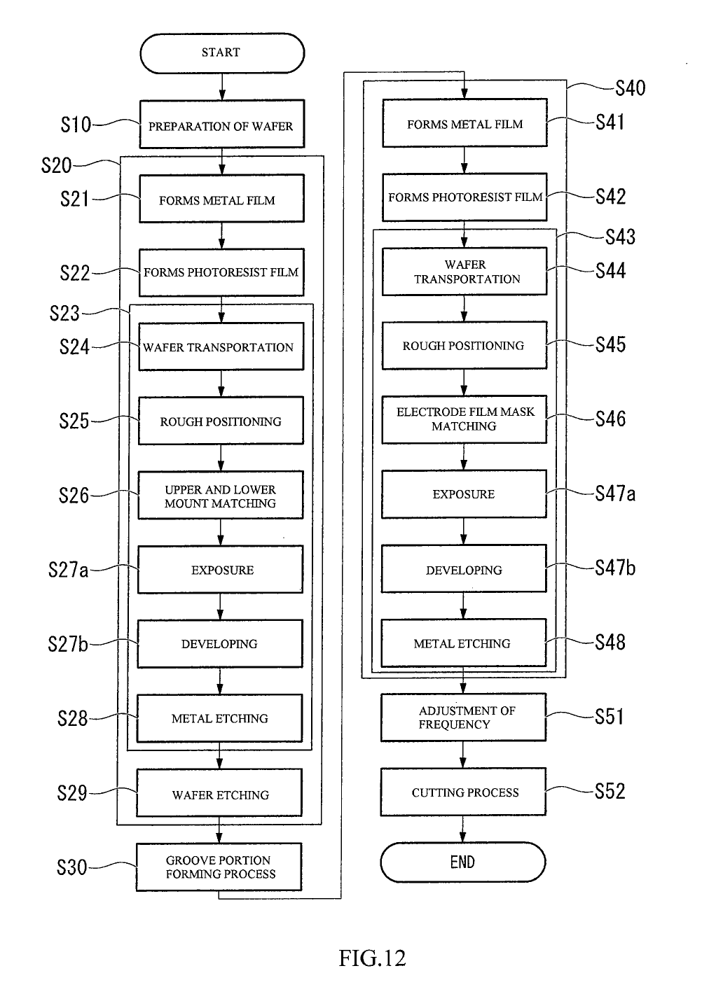

Next, a method of manufacturing the piezoelectric vibrating reed forming the piezoelectric vibrating reed 4 using the manufacturing apparatus 40 configured in this manner will be described based on FIGS. 12 to 15.

FIG. 12 is a flow chart of the method of manufacturing the piezoelectric vibrating reed.

As shown in FIG. 12, firstly, a Lambert ore of crystal is sliced at a predetermined angle to form a wafer S of a certain thickness. Next, after the wafer S is wrapped and roughly worked, the damaged layer is removed by etching, and then a mirror polishing process such as polishing is performed, thereby forming the wafer S of a predetermined thickness (S10).

Next, an external form forming process of forming a plurality of external forms of the piezoelectric plate 24 on the wafer S after the polishing is performed (S20).

At this time, firstly, on both surfaces of the wafer S, a protective film (not shown), for example, formed by the stacking of a chrome layer, a gold layer or the like is formed, for example, by a vapor deposition method, a sputtering method or the like (S21).

Next, a photoresist film (a mask material for the piezoelectric plate) is formed on the protective film (S22).

Next, a resist pattern forming process for forming a desired resist pattern on the photoresist film is performed (S23). Hereinafter, the resist pattern forming process in the external form forming process will be described in detail.

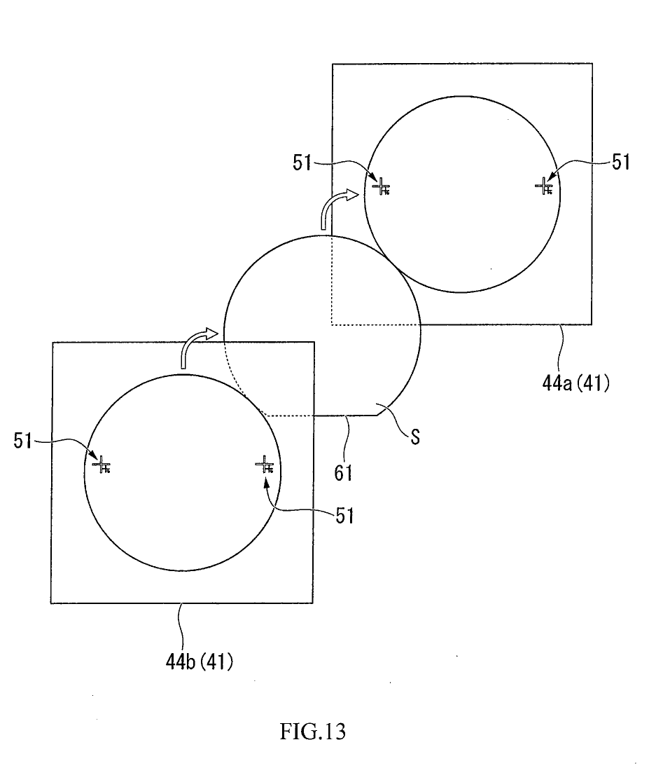

FIG. 13 is a process diagram of the resist pattern forming process in the external form forming process.

As shown in FIGS. 8, 12 and 13, firstly, the wafer S is transported (S24) onto the lower external form mask 44a (41). Moreover, rough positioning of the wafer S is performed (S25) on the lower external form mask 44a (41). Since a notch-shaped orientation flat 61 formed at one side thereof is provided in the wafer S, the rough positioning may be performed by the use of the orientation flat 61.

After performing the rough positioning, the upper external form mask 44b is placed on the upper surface of the wafer S, that is, a surface opposite to the lower external form mask 44a, and the alignment of the upper and lower external form masks 44a and 44b (S26, an external form mask placing process).

The alignment is performed by the use of the external form mask side mark group 51 formed in the respective external form masks 44a and 44b. That is, the wafer S placed on the lower external form mask 44a is able to see the external form mask side mark group 51 formed in the lower external form mask 44a from the upper surface. For this reason, a worker performs the alignment of both of the external form masks 44a and 44b by superimposing the external form mask side mark group 51 formed in the upper external form mask 44b on the external form mask side mark group 51 formed in the lower external form mask 44a by the use of a microscope (not shown).

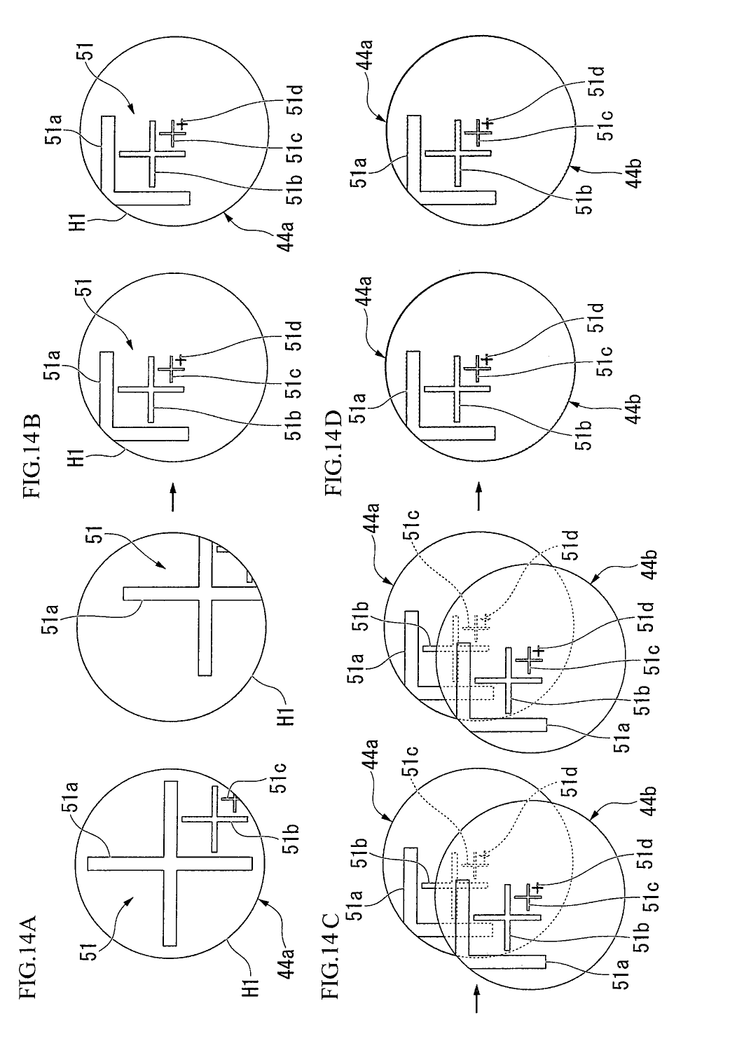

FIGS. 14A to 14D are operation process diagrams that show an alignment method of the external form mask side mark group 51 formed in both of the external form masks 44a and 44b.

Herein, the external form mask side mark group 51 is constituted by a plurality (four in the present embodiment) of external form mask side marks 51a to 51d (see FIG. 11). For this reason, firstly, as shown in FIG. 14A, a position of the largest external form mask side mark 51a in the external form mask side mark group 51 formed in the lower external form mask 44a is specified (an external form mark group detecting process).

At this time, the positions of the relatively small external form mask side marks 51c and 51d may be specified, but as the external form mask side marks 51c and 51d are smaller, it is hard to see the same. For this reason, by operating so as to specify the largest external form mask side mark 51a, even if the small external form mask side masks 51c and 51d are out of the range of a field of view H1 of a microscope (not shown), it is possible to easily specify the position of the largest external form mask side mark 51a.

Next, as shown in FIG. 14B, the position of the smallest external form mask side mark 51d is specified from the position of the largest external form mask side mark 51a.

Meanwhile, even in the external form mask side mark group 51 formed in the upper external form mask 44b, the position of the smallest external form mask side mark 51d is specified in the same sequence as the external form mask side mark group 51 formed in the lower external form mask 44a. That is, firstly, the largest external form mask side mark 51a is specified, and the position of the smallest external form mask side mark 51d is specified from the external form mask side mark 51a.

Next, as shown in FIG. 14C, the smallest external form mask side mark 51d formed in the upper external form mask 44b approaches the smallest external form mask side mark 51d formed in the lower external form mask 44a.

Moreover, as shown in FIG. 14D, the positions of the smallest external form mask side marks 51d and 51d formed in the respective external form masks 44a and 44b are aligned, and the alignment of the upper and lower external form masks 44a and 44b (S26) is completed. In this manner, by using the smallest external form mask side mark 51d, the alignment of the upper and lower external form masks 44a and 44b can be accurately performed. That is, the smallest external form mask side mark 51d is used as the alignment purpose of the respective mark groups 51 and 51, and all of the external form mask side marks 51a to 51d including the external form mask side mark 51d are used in the external form mark group detecting process.

As shown in FIG. 12, after placing the external form masks 44a and 44b on the wafer S, a resist pattern is exposed to a photoresist film (not shown) on both surfaces of the wafer S via the external form masks 44a and 44b (S27a). When the exposure is finished, the external form masks 44a and 44b are removed, and then, the photoresist film is developed, thereby removing the exposure portion (S27b).

After that, the metal etching is performed to remove the exposed protective film form the exposure portion, and the resist film is removed (S28).

Moreover, a crystal etching is performed to etch the exposed wafer S from the removal portion of the protective film (S29), and then the protective film is removed, whereby the external form forming process (S20) is finished.

FIG. 15 is a plan view of the wafer in which the external form forming process is finished.

As shown in FIG. 15, in the wafer S in which the external form forming process (S20) is finished, the external form of the piezoelectric plate 24 is formed. More specifically, in a plate forming region S2 existing inside an outer peripheral portion Si of the wafer S, an external form of the piezoelectric plate 24 is formed.

The plate forming region S2 is a portion exposed from the exposure portion 41a of the external form mask 41, and in the plate forming region S2, a portion except for the external form of the piezoelectric plate 24 and a connection portion (not shown) connecting the external form with the outer peripheral portion Si is removed by the crystal etching.

Herein, the external form mask 41 is formed with the external form mask side mark group 51. For this reason, the wafer S is formed with the external form of the piezoelectric plate 24, and the wafer side mark group 71 is formed in a region corresponding to two external form mask side mark groups 51. Since the wafer side mark group 71 is also formed via the same process (the external form forming process (S20)) as the piezoelectric plate 24, the wafer side mark group 71 is formed in the same shape as the external form mask side mark group 51.

That is, as shown in FIG. 11, the wafer side mark group 71 is constituted by a plurality of wafer side marks 71a to 71d that is formed in a cross shape and has the sizes different from each other. Furthermore, the wafer side mark group 71 is constituted by a penetration hole that penetrates the wafer S in the thickness direction, or a concave portion that is formed on the surface of the wafer S.

As shown in FIGS. 5 to 7 and 12, after performing the external form forming process (S20), a groove portion forming process (S30) of forming a groove portion 18 in the pair of vibration arm portions 10 and 11 is performed, and then an electrode forming process of performing the excitation electrode 15 and a weight metal film 21 in the wafer S formed with the external form of the piezoelectric plate 24 is performed (S40).

At this time, firstly, on the piezoelectric plate 24, a metal film (not shown) becoming an electrode is formed by, for example, a vapor deposition method, a sputtering method or the like (S41).

Next, a photoresist film (an electrode film mask material) is formed on the metal film (S42).

Next, a resist pattern forming process for forming a resist pattern becoming the electrode shape on the photoresist film is performed (S43). The resist pattern forming process in the electrode forming process will be described in detail below.

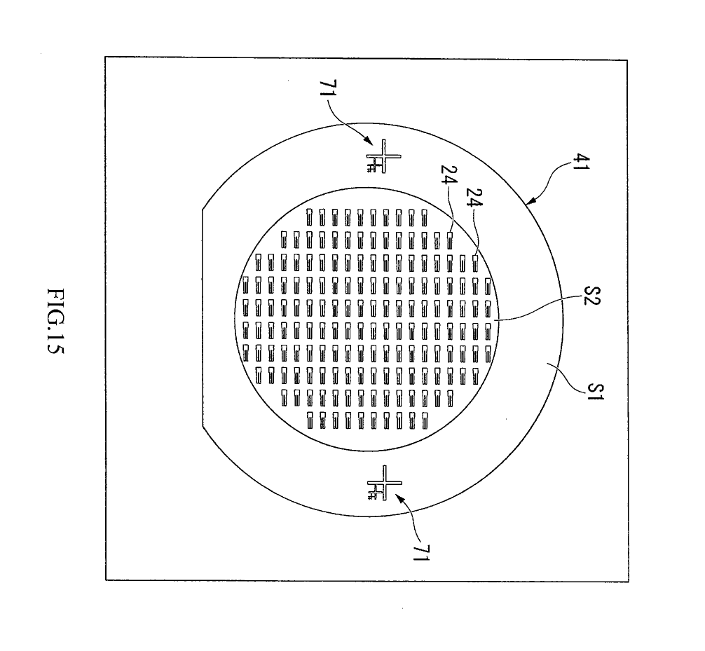

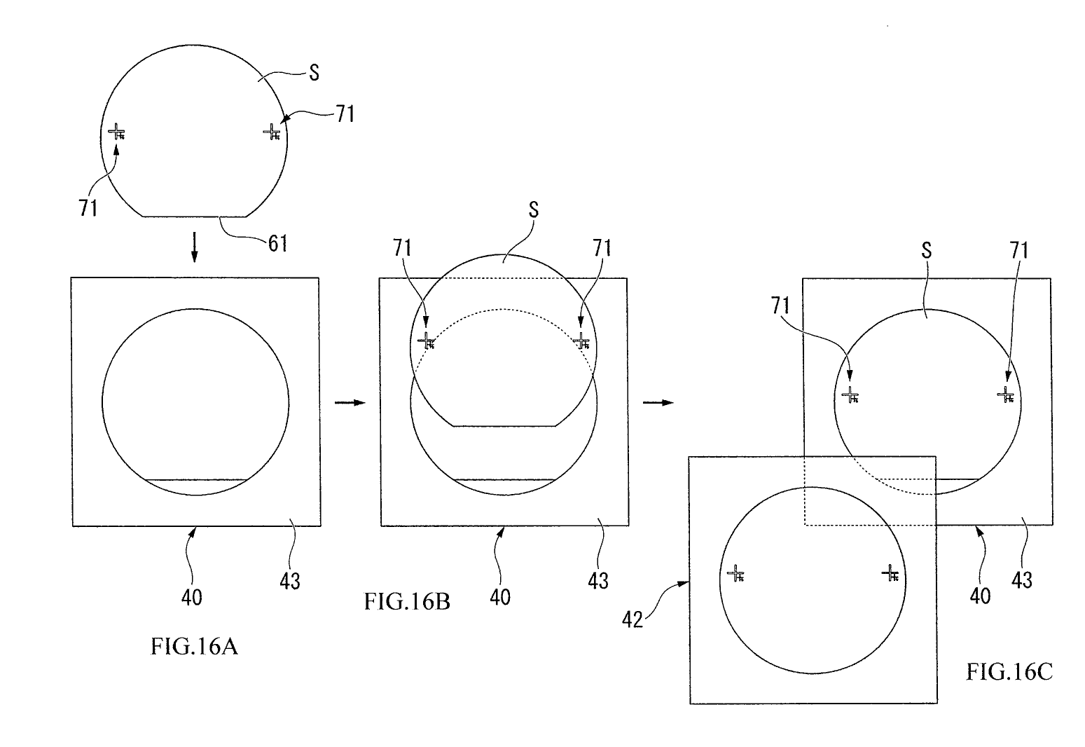

FIGS. 16A to 16C are process diagrams of the resist pattern forming process in the electrode forming process.

As shown in FIGS. 12 and 16A to 16C, firstly, the wafer S is transported onto the work stage 43 of the manufacturing apparatus 40 (S44, see FIGS. 16A and 16B). Moreover, the rough positioning for the wafer S is performed on the work stage 43 (S45). At this time, the rough positioning is performed by the use of the orientation flat 61 or the like provided in the wafer S.

After performing the rough positioning, the electrode film mask 42 (see FIG. 9) is placed on a surface at a side opposite to the work stage 43, and the alignment of the electrode film mask 42 is performed (S46, an electrode mask placing process).

The alignment is performed by the use of the wafer side mark group 71 formed in the wafer S and the electrode mask side mark group 52 formed in the electrode film mask 42. Herein, the alignment between the wafer side mark group 71 and the electrode mask side mark group 52 is identical to the alignment between the external form mask side mark group 51 formed the lower external form mask 44a and the external form mask side mark group 51 formed in the upper external form mask 44b mentioned above.

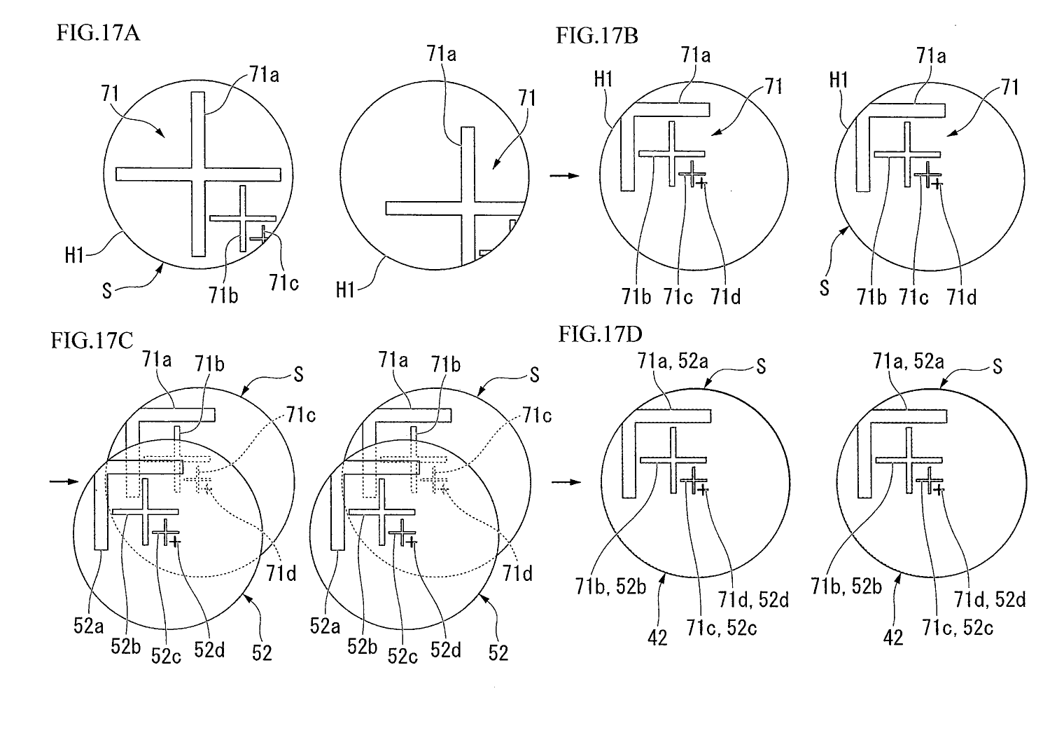

FIGS. 17A and 17B are operation process diagrams for aligning the electrode mask side mark group 52 formed in the electrode film mask 42 to the wafer side mark group 71 formed in the wafer S.

That is, firstly, as shown in FIG. 17A, the position of the largest wafer side mark 71a in the wafer side mark group 71 is specified (an electrode mark group detecting group).

Next, as shown in FIG. 17B, the position of the smallest wafer side mark 71d is specified from the position of the largest wafer side mark 71a.

Meanwhile, even in the electrode mask side mark group 52 formed in the electrode film mask 42, the position of the smallest electrode mask side mark 52d is specified in the same order as the wafer side mark group 71. That is, firstly, the largest electrode mask side mark 52a is specified, and the position of the smallest electrode mask side mark 52d is specified from the electrode mask side mark 52a.

Next, as shown in FIG. 14C, the smallest electrode mask side mark 52d approaches the smallest wafer side mark 71d.

Moreover, as shown in FIG. 14D, the position of the wafer side mark 71d is aligned with the position of the electrode mask side mark 52d, and the alignment (S46) of the electrode film mask 42 to the wafer S is completed. In this manner, by using the smallest wafer side mark 71d and the smallest electrode mask side mark 52d, the alignment of the electrode film mask 42 can be accurately performed. That is, the smallest electrode mask side mark 52d and the wafer side mark 71d are used for the alignment between the electrode mask side mark group 52 and the wafer side mark group 71, and all of the electrode mask side marks 52a to 52d and the wafer side marks 71a to 71d including the electrode mask side mark 52d and the wafer side mark 71d are used in the electrode mark group detecting process.

As shown in FIG. 12, after placing the electrode film mask 42 on the wafer S, a resist pattern is exposed onto a photoresist film (not shown) via the electrode film mask 42 (S47a). When the exposure is finished, after the electrode film mask 42 is removed, the photoresist film is developed, and the exposure portion is removed (S47b).

Moreover, the remaining photoresist film is subjected to the metal etching as a mask and is patterned. After that, by removing the masked photoresist film, the excitation electrode 15 and the weight metal film 21 are formed, and the electrode forming process (S40) is finished.

After performing the electrode forming process (S40), a rough adjustment process of rough adjusting the resonance frequency is performed on all of the vibration arm portions 10 and 11 formed in the wafer S (S51).

This is, for example, a process of irradiating the rough adjustment film 21a (see FIGS. 5 and 6) of the weight metal film 21 with laser light, and reducing the weight applied to the tips of the pair of vibration arm portions 10 and 11, thereby roughly adjusting the frequency.

Next, a cutting process of cutting a connection portion (not shown) connecting the wafer S with the piezoelectric vibrating reed 4, and separating the plurality of piezoelectric vibrating reeds 4 from the wafer S into small pieces is performed (S52). As a result, it is possible to manufacture the piezoelectric vibrating reed 4 formed with the excitation electrode 15, the mount electrodes 16 and 17, drawing electrodes 19 and 20, and the weight metal film 21 from the wafer S at a time.

### (Effects)

Thus, according to the embodiment mentioned above, the alignment mark used in the alignment of the external form mask 41 is the external form mask side mark group 51 which includes a plurality of external form mask side marks 51a to 51d, the alignment mark used in the alignment between the wafer S and the electrode film mask 42 is the wafer side mark group 71 constituted by the plurality of wafer side marks 71a to 71d and the electrode mask side mark group 52 constituted by the plurality of electrode mask side marks 52a to 52d, and the smallest marks 51d, 52d, and 71d are sequentially specified from the largest marks 51a, 52a, and 71a, whereby the smallest marks 51d, 52d, and 71d can be rapidly specified. Furthermore, when further specifying the external form forming process (S20) or the electrode forming process (S40) by using the smallest marks 51d, 52d, and 71d in the alignment, it is possible to easily and accurately specify the resist pattern forming processes (S23 and S43).

Furthermore, in the respective marks 51a to 71d, three marks 51b to 71d except for the largest marks 51a to 71a are placed in the forming range W1 of the largest marks 51a to 71a. In addition to this, the respective marks 51a to 71d are placed in a predetermined arrangement pattern so as to sequentially deviate to the right lower side in FIG. 11 as the mark is reduced from the largest marks 51a to 71a.

For this reason, since the position of the smallest marks 51d to 71d can be easily predicted at the point in time when specifying the largest marks 51a to 71a, it is possible to improve the operational efficiency after specifying the largest marks 51a to 71a until specifying the smallest marks 51d to 71d.

Furthermore, by forming the respective marks 51a to 71d in a cross shape, other marks 51b to 71d can be placed in the forming range W1 of the largest marks 51a to 71a.

That is, for example, when forming the respective external form mask side marks 51a to 51d in a circular shape, it is difficult to form other external form mask side marks 51b to 51d inside the circle of the largest external form mask side mark 51a. For this reason, there is a need to increase the range of placing the plurality of external form mask side marks 51a to 51d.

However, since other external form mask side marks 51b to 51d can be formed in the forming range W1 of the largest external form mask side mark 51a by forming the external form mask side marks 51a to 51d in a cross shape, it is possible to promote space reductions in the range in which the external form mask side marks 51a to 51d are placed. In this manner, it is also possible to promote space reductions in the range in which the respective marks 52a to 71d are placed.

### (Oscillator)

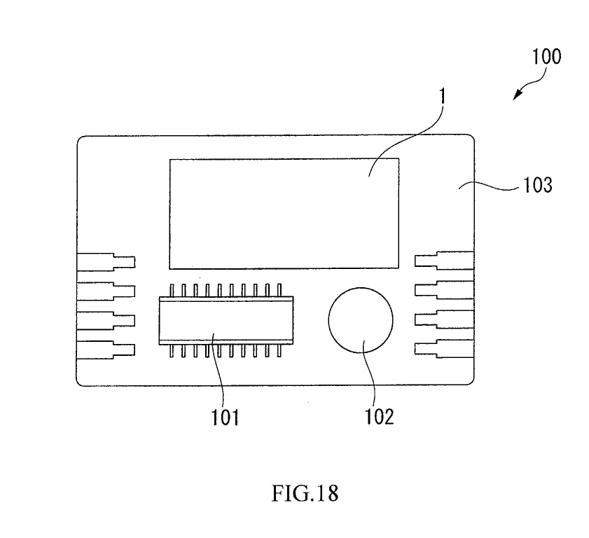

Next, an embodiment of an oscillator according to the present invention will be described based on FIG. 18.

FIG. 18 is a configuration diagram of the oscillator.

As shown in FIG. 18, the oscillator 100 is configured as an oscillating element in which the piezoelectric vibrator 1 is electrically connected to an integrated circuit 101. The oscillator 100 includes a substrate 103 with an electronic component 102 such as a condenser mounted thereon. The integrated circuit 101 for the oscillator mentioned above is mounted on the substrate 103, and the piezoelectric vibrator 1 is mounted near the integrated circuit 101. The electronic component 102, the integrated circuit 101, and the piezoelectric vibrator 1 are electrically connected by a wiring pattern (not shown). In addition, the respective components are molded by resin (not shown).

In the oscillator 100 configured in this manner, upon applying the voltage to the piezoelectric vibrator 1, the piezoelectric vibrating reed 4 in the piezoelectric vibrator 1 is vibrated. The vibration is converted to the electric signal by the piezoelectric characteristic of the piezoelectric vibrating reed 4 and is input to the integrated circuit 101 as the electric signal. The input electric signal is subjected to various processes by the integrated circuit 101 and is output as the frequency signal. As a result, the piezoelectric vibrator 1 functions as the oscillating element.

Furthermore, by selectively setting the configuration of the integrated circuit 101, for example, a RTC (Real Time Clock) module or the like depending on demand, it is possible to add a function of controlling an operation date or a time of the apparatus or external apparatus other than a single-function oscillator for the timepiece or the like, or providing a time, a calendar or the like.

### (Effects)

Thus, according to the oscillator 100 mentioned above, since the low-cost reliable piezoelectric vibrator 1 is included, the oscillator itself is also able to promote a reduction in cost. Furthermore, in addition to this, it is possible to obtain a high precision frequency signal that is stable for a long period of time.

### (Electronic Apparatus)

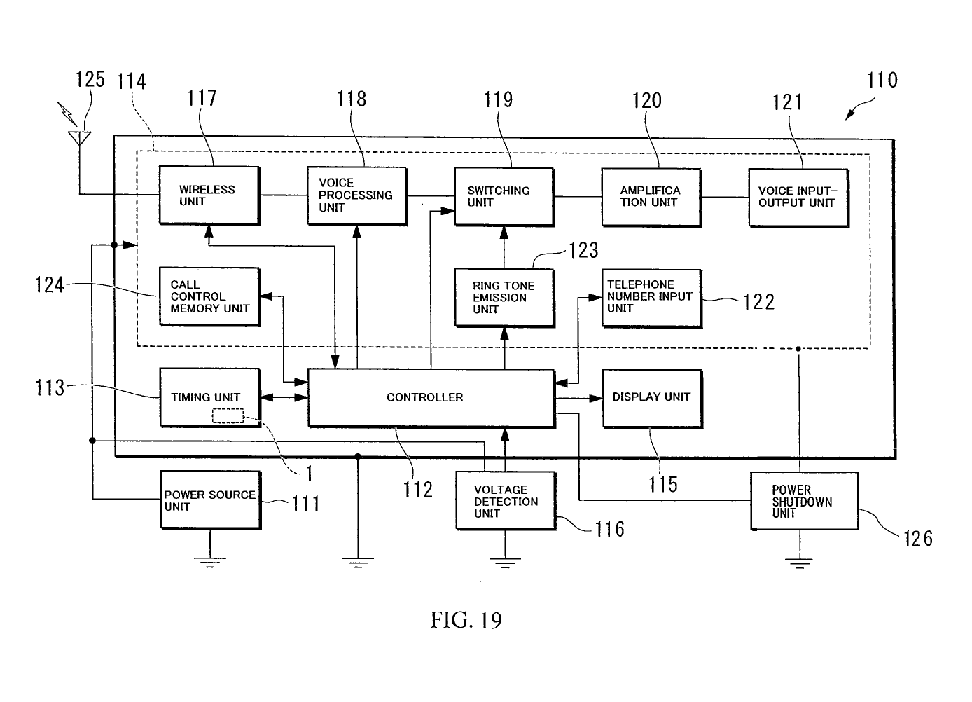

Next, an embodiment of the electronic apparatus according to the present invention will be described based on FIG. 19. Furthermore, as the electronic apparatus, a portable information apparatus 110 having the piezoelectric vibrator 1 will be described as an example.

FIG. 19 is a configuration diagram of a portable information apparatus that is an electronic apparatus.

As shown in FIG. 19, the portable information apparatus 110 is represented by, for example, a mobile phone, and is an apparatus that develops and improves a wristwatch in the related art. The exterior thereof is similar to the wristwatch, a liquid crystal display is disposed in a portion corresponding to a text plate, and a current time or the like can be displayed on the screen. Furthermore, in the case of being used as a communicator, the apparatus is removed from the wrist, and the communication like the mobile phone of the related art can be performed by a speaker and a microphone equipped in the inner portion of the band. However, the apparatus is considerably reduced in size and weight compared to the mobile phone of the related art.

Next, a configuration of portable information apparatus 110 of the present embodiment will be described. The portable information apparatus 110 includes the piezoelectric vibrator 1 and a power source portion 111 for supplying the electric power. For example, the power source portion 111 is formed of a lithium secondary battery. A control portion 112 performing various controls, count portions 113 performing the count such as the time, a communication portion 114 performing the communication with the outside, a display portion 115 displaying various pieces of information, and a voltage detection portion 116 detecting the voltage of the respective function portions are connected to the power source portion 111 in parallel. Moreover, the electric power is supplied to the respective function portions by the power source portion 111.

The control portion 112 performs the respective function portions, and performs the operation control of the whole system such as reception and the transmission of the sound data, measurement and display of the current time or the like. Furthermore, the control portion 112 includes a ROM with a program written in advance therein, a CPU reading and executing the program written in the ROM, a RAM used as a work area of the CPU or the like.

The count portion 113 includes an integrated circuit equipped with an oscillation circuit, a register circuit, a counter circuit, an interface circuit or the like, and the piezoelectric vibrator 1. When applying the voltage to the piezoelectric vibrator 1, the piezoelectric vibrating reed 4 is vibrated, and the vibration is converted into the electric signal by the piezoelectric characteristic of crystal and is input to the oscillation circuit as the electric signal. The output of the oscillation circuit is binarized and is counted by the register circuit and the counter circuit. Moreover, the signal is received and transmitted together with the control portion 112 via the interface circuit, and the current time, the current date, the calendar information or the like are displayed on the display portion 115.

The communication portion 114 has the same function as the mobile phone of the related art, and includes a wireless portion 117, a sound process portion 118, a switching portion 119, an amplification portion 120, a sound input and output portion 121, a phone number input portion 122, a ringtone generating portion 123, and a call control memory portion 124.

The wireless portion 117 exchanges the transmission and the reception of various pieces of information such as the sound data with a base station via an antenna 125. The sound process portion 118 encodes and decodes the sound signal that is input from the wireless portion 117 or the amplification portion 120. The amplification portion 120 amplifies the signal, which is input from the sound process portion 118 or the sound input and output portion 121, up to a predetermined level. The sound input and output portion 121 is constituted by a speaker, a microphone or the like, amplifies the ringtone or the received sound or collects the sound.

Furthermore, the ringtone generating portion 123 creates the ringtone depending on the call from the base station. The switching portion 119 switches the amplification portion 120 connected to the sound process portion 118 into the ringtone generating portion 123 only at the time of the reception, whereby the ringtone created in the ringtone generating portion 123 is output to the sound input and output portion 121 via the amplification portion 120.

In addition, the call control memory portion 124 stores the program relating to the call arrival and departure control of the communication. Furthermore, the phone number input portion 122 includes, for example, number keys from 0 to 9, and other keys, and a phone number or the like of a communication target is input by pressing the number keys or the like.

When the voltage added to the respective function portions such as the control portion 112 by the power source portion 111 is lower than a predetermined value, the voltage detection portion 116 detects the voltage drop and notifies the same to the control portion 112. The predetermined voltage value of this time is a value which is set as a minimum voltage required for stably operating the communication portion 114 in advance, and, for example, is about 3 V. The control portion 112 received the notification of the voltage drop from the voltage detection portion 116 prevents the operation of the wireless portion 117, the sound process portion 118, the switching portion 119, and the ringtone generating portion 123. Particularly, the stopping of the operation of the wireless portion 117 which has high power consumption is essential. In addition, an indication is displayed on the display portion 115 in which the communication portion 114 is unusable from the shortage of the battery residual amount.

That is, the operation of the communication portion 114 is prevented by the voltage detection portion 116 and the control portion 112, and the indication thereof can be displayed on the display portion 115. The display may be a text message, but an X (false) mark may be displayed on a phone icon displayed on the upper portion of the display surface of the display portion 115 as a more intuitive display.

In addition, a power source blocking portion 126 capable of selectively cutting the power source of a portion relating to the function of the communication portion 114 is included, whereby the function of the communication portion 114 can be further reliably stopped.

### (Effects)

Thus, according to the portable information apparatus 110 mentioned above, since the low-cost reliable piezoelectric vibrator 1 is included, the portable information apparatus itself is also able to promote a reduction in cost. Furthermore, in addition to this, stable and high-precision timepiece information can be displayed for a long period of time.

### (Radio Timepiece)

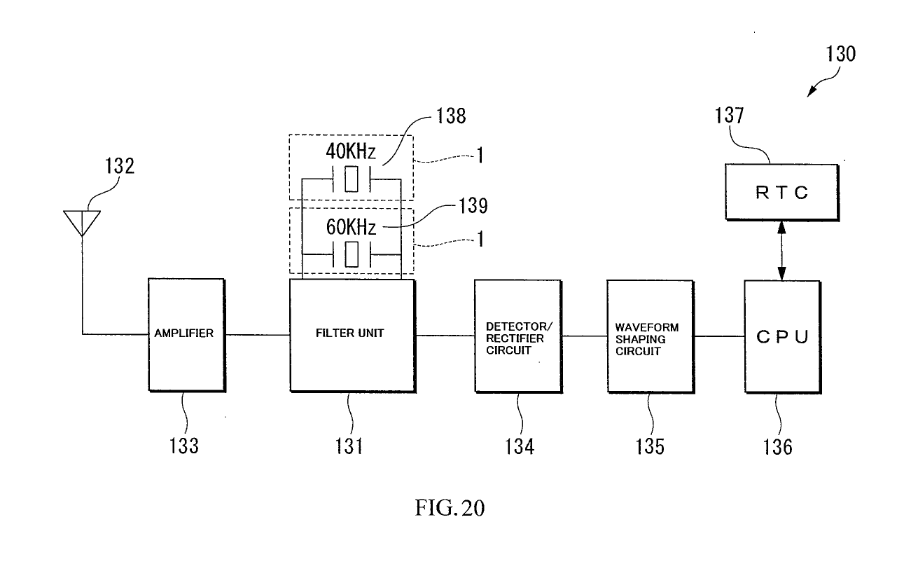

Next, an embodiment of a radio timepiece according to the present invention will be described based on FIG. 20.

FIG. 20 is a configuration diagram that shows an embodiment of the radio timepiece.

As shown in FIG. 20, the radio timepiece 130 of the present embodiment includes the piezoelectric vibrator 1 electrically connected to a filter portion 131, and is a timepiece that has a function of receiving standard radio waves including the timepiece information and automatically correcting and displaying the same at a correct time.

In Japan, in Fukushima Prefecture (40 kHz) and Saga Prefecture (60 kHz), there are transmission stations (transmission departments) transmitting the standard radio waves, and transmitting the standard radio waves, respectively. Since long waves such as 40 kHz or 60 kHz together have the property of being propagated along the surface of the earth and the property of propagating while being reflected between the ionization layer and the surface of the Earth, the propagation range is wide, and the two transmission stations cover all of Japan.

Hereinafter, a functional configuration of the radio timepiece 130 will be specifically described.

The antenna 132 receives the standard radio waves having a 40 kHz or 60 kHz long wave. An AM modulation of the standard long wave radio waves is performed on the 40 kHz or 60 KHz carrier wave, to provide the time information called a time code. The received standard radio waves of the long wave are amplified by an amplifier 133, and are filtered and tuned by a filter portion 131 having a plurality of piezoelectric vibrators 1.

The piezoelectric vibrator 1 in the present embodiment includes crystal vibrator portions 138 and 139 having the same resonance frequency of 40 kHz and 60 kHz as the carrier frequency mentioned above, respectively.

In addition, the filtered signal of a predetermined frequency is detected and demodulated by a detection and rectifier circuit 134. Next, the time code is extracted via a waveform shaping circuit 135 and is counted by the CPU 136. In the CPU 136, information such as the current year, cumulative date, day of week, and time are read. The read information is reflected in the RTC 137 and the correct time information is displayed.

Since the carrier wave is 40 kHz or 60 kHz, a vibrator having the tuning fork-like structure mentioned above is preferable as the crystal vibration portions 138 and 139.

In addition, the description mentioned above illustrated the example of Japan, but the frequency of the standard radio waves of the long wave differs abroad. For example, standard radio waves of 77.5 kHz are used in Germany. Thus, when the radio timepiece 130 capable of support abroad as well is built in the portable apparatus, there is a need for the piezoelectric vibrator 1 having a frequency which differs from the case of Japan.

### (Effects)

Thus, according to the radio timepiece 130 mentioned above, since it includes the low-cost reliable piezoelectric vibrator 1, a cost reduction is also able to be promoted in the radio timepiece itself. Furthermore, in addition to this, it is possible to stably and accurately count the time for a long period of time.

In addition, the technical scope of the present invention is not limited to the embodiment mentioned above, and various modifications can be added within the scope not departing from the gist of the present invention.

For example, in the embodiment mentioned above, a case was described where an external form mask side mark group 51 is formed as the alignment mark on the external form mask 41 used when manufacturing the piezoelectric vibrator 1, the electrode mask side mark group 52 is formed as the alignment mark on the electrode film mask 42, and the mark groups 51 and 52 are constituted by cross-shaped marks 51a to 52d. Furthermore, a case was described where, in FIG. 11, the respective marks 51a to 52d are placed so as to gradually deviate from the largest marks 51a and 52a to the right lower side in the sequence of the large mark. However, the respective groups 51 and 52 may be constituted by at least two marks having sizes different from each other without being limited thereto, and the shape thereof is not limited to the cross shape. Furthermore, each mark may be placed in a predetermined arrangement pattern, and the arrangement pattern of each mark is not limited to the arrangement pattern shown in FIG. 11.

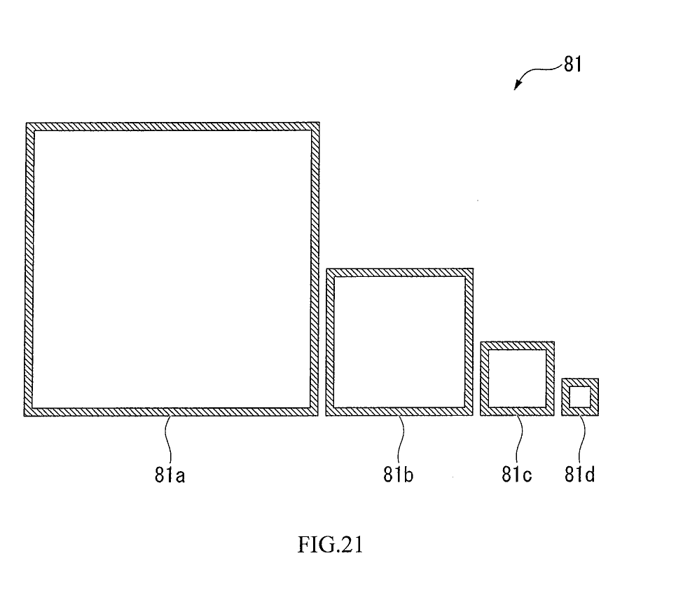

More specifically, for example, a mark group 81 shown in FIG. 21 may be adopted.

FIG. 21 is a detail view of another embodiment of each mark group.

As shown in FIG. 21, the mark group 81 is constituted by a plurality (for example four) of marks 81a to 81d. The respective marks 81a to 81d are formed in a square-shaped frame shape and the sizes thereof are different from each other. Moreover, the marks are sequentially placed toward the right side in FIG. 21 from the largest mark 81a to the smallest mark 81d.

Even when the alignment of the external form mask 41 and the alignment of the electrode film mask 42 are performed by the use of the mark group 81 configured in this manner, the same effect as mentioned above can be obtained.

What is claimed is:

1. A method of manufacturing a piezoelectric vibrating reed that includes a piezoelectric plate, and an electrode portion which vibrates the piezoelectric plate when voltage is applied, the method comprising:
an external form forming process of applying a piezoelectric plate forming mask material onto both surfaces of a wafer formed of a piezoelectric material, then, placing a pair of external form masks prepared for the forming of piezoelectric plate, and then irradiating light via the external form masks to form an external form of the piezoelectric plate; and
a resist pattern forming process of applying an electrode film mask material to the wafer formed with an external form of the piezoelectric plate, then placing an electrode film mask prepared for an electrode film, and then irradiating light via the electrode film mask to form a resist pattern,
wherein the resist pattern forming process includes
an electrode mark group detecting process of detecting a wafer side mark group formed in the wafer, an electrode mask side mark group formed in the electrode film mask, and
an electrode mask placing process of placing the electrode film mask on the wafer while aligning the wafer side mark group and the electrode mask side mark group,
the wafer side mark group is constituted by at least two wafer side marks having sizes different from each other,
the electrode mask side mark group is constituted by at least two electrode mask side marks having sizes different from each other, and
the smallest wafer side mark and the electrode mask side mark are used for the alignment of the mutual marks, respectively, and all of the wafer side mark and the electrode mask side mark except for the smallest wafer side mark and the electrode mask side mark are used in the electrode mark group detecting process.

2. The method according to claim 1,
wherein each wafer side mark and each electrode mask side mark are placed in a predetermined arrangement pattern, respectively.

3. The method according to claim 2,
wherein the respective wafer side marks are configured so that another wafer side mark is placed in a forming range of the largest wafer side mark, and
the respective electrode mask side marks are configured so that another electrode mask side mark is placed in a forming range of the largest electrode mask side mark.

4. A method of manufacturing a piezoelectric vibrating reed that includes a piezoelectric plate, and an electrode portion which vibrates the piezoelectric plate when voltage is applied, the method comprising:
an external form forming process of applying a piezoelectric plate forming mask material onto both surfaces of a wafer formed of a piezoelectric material, then, placing a pair of external form masks prepared for the forming of piezoelectric plate, and then irradiating light via the external form masks to form an external form of the piezoelectric plate; and
a resist pattern forming process of applying an electrode film mask material to the wafer formed with an external form of the piezoelectric plate, then placing an electrode film mask prepared for an electrode film, and then irradiating light via the electrode film mask to form a resist pattern,
wherein the external form forming process includes
an external form mark group detecting process of detecting an external form mask side mark group formed in each external form mask, and
an external form mask placing process of placing each external form mask on the wafer while aligning position of the external form mask side mark group of each external form mask,
wherein the external form mask side mark group is constituted by at least two external form mask side marks having sizes different from each other,
the smallest external form mask side mark formed in each external form mask is used for the alignment of the mutual marks, and all of the external form mask side marks except for the smallest external form mask side mark are used in the external form mark group detecting process.

5. The method according to claim 4,
wherein the respective external form mask side marks are placed in a predetermined arrangement pattern, respectively.

6. The method according to claim 5,
wherein the respective external form mask side marks are configured so that another external form mask side mark is placed in a forming range of the largest external form mask side mark.
